(19) United States
(12) Patent Application Publication
(10) Pub. No.: US 2026/0090014 A1
(43) Pub. Date: Mar. 26, 2026

(54) THIN FILM TRANSISTOR SUBSTRATE AND DISPLAY DEVICE COMPRISING THE SAME

(71) Applicant: LG Display Co., Ltd., Seoul (KR)

(72) Inventors: JaeHyun KIM, Paju-si (KR); Sohyung LEE, Paju-si (KR)

(73) Assignee: LG Display Co., Ltd., Seoul (KR)

(21) Appl. No.: 19/298,601

(22) Filed: Aug. 13, 2025

(30) Foreign Application Priority Data
Sep. 26, 2024 (KR) 10-2024-0131062

(51) Int. Cl. H10D 30/67; H10D 86/40; H10D 86/60; H10K 59/121

(52) U.S. Cl. CPC H10D 30/6704; H10D 30/6731; H10D 30/6743; H10D 30/6755; H10D 86/423; H10D 86/60; H10K 59/1213

(57) ABSTRACT

Discussed is a thin film transistor substrate and a display device using the same. The thin film transistor substrate comprises: a first thin film transistor and a second thin film transistor disposed on a substrate, the first thin film transistor including a first active layer disposed on the substrate and including a silicon semiconductor material, a hydrogen supply layer disposed on the first active layer, a hydrogen barrier layer disposed on the hydrogen supply layer, and a first gate electrode disposed on the hydrogen barrier layer, and the second thin film transistor including a second active layer disposed on the hydrogen barrier layer and including an oxide semiconductor material.

### CROSS-REFERENCE TO RELATED APPLICATION

This application claims priority to Korean Patent Application No. 10-2024-0131062, filed in the Republic of Korea on Sep. 26, 2024, which is hereby expressly incorporated by reference in its entirety into the present application.

### BACKGROUND

### Field of Technology

The present disclosure relates to a thin film transistor substrate and a display device using the same.

### Discussion of the Related Art

With the advent of information society, demands for display devices for displaying images that provide information are increasing in various forms. Accordingly, various display devices such as liquid crystal displays (LCD), plasma display panels (PDP), and organic light emitting displays (OLED) are being utilized recently to provide large amount of information.

Among display devices, organic light emitting display devices are self-luminous, and have superior viewing angles and contrast ratios compared to liquid crystal displays (LCD), and do not require a separate backlight, making them lightweight and thin, and have the advantage of low power consumption. In addition, organic light emitting display devices can be driven by low direct current voltage, have a fast response speed, and have the advantage of low manufacturing costs. Such devices are well suited for displaying large amounts of information efficiently.

Thin film transistors can include polycrystalline silicon thin film transistors made by crystallizing amorphous silicon after deposition, and oxide semiconductor thin film transistors made of oxide semiconductor materials.

In this case, polycrystalline silicon thin film transistors have the advantages of high electron mobility, excellent stability, thin thickness, high resolution, and high power efficiency. These polycrystalline silicon thin film transistors include low temperature poly silicon (LTPS) thin film transistors, or polysilicon thin film transistors.

Oxide semiconductor thin film transistors have an advantage in that desired property can be easily obtained because the oxide semiconductor TFTs have a large resistance change depending on the oxygen content. In addition, since the oxide constituting the active layer can be formed at a relatively low temperature during the manufacturing process of the oxide semiconductor thin film transistor, the manufacturing cost is low. Since the oxide semiconductor is transparent due to the characteristic of the oxide, it is also advantageous in implementing a transparent display.

Recently, performance-enhanced display devices have been implemented by appropriately combining low-temperature polycrystalline silicon thin film transistors (LTPS TFT) and oxide semiconductor thin film transistors (Oxide TFT). However, since low-temperature polycrystalline silicon thin film transistors (LTPS TFT) require hydrogen to be supplied for crystallization and oxide semiconductor thin film transistors (Oxide TFT) must be prevented from having their characteristic changed by hydrogen, efforts are being made to provide an optimized structure to address this issue.

### SUMMARY OF THE DISCLOSURE

The present disclosure has been designed in view of the mentioned problem, and aims to provide a thin film transistor substrate and a display device that do not deteriorate the performance of oxide semiconductor thin film transistors and polysilicon thin film transistors, respectively, by selectively supplying and/or blocking hydrogen to the oxide semiconductor thin film transistor and the polysilicon thin film transistor.

In order to achieve the above object, the present disclosure provides a thin film transistor substrate and a display device using the same. The thin film transistor substrate comprises a base substrate, a first thin film transistor and a second thin film transistor on the base substrate, wherein the first thin film transistor includes a first active layer disposed on the base substrate and including a silicon semiconductor material, a hydrogen supply layer on the first active layer, a first hydrogen barrier layer on the hydrogen supply layer, and a first gate electrode on the first hydrogen barrier layer, wherein the second thin film transistor comprises a second active layer on the first hydrogen barrier layer and including an oxide semiconductor material, and a second gate electrode on the second active layer.

Furthermore, the present disclosure provides a thin film transistor substrate including a base substrate including a display area and a non-display area, a first thin film transistor on the base substrate and including a silicon semiconductor material, a second thin film transistor including an oxide semiconductor material, a first hydrogen barrier layer disposed to overlap the first thin film transistor and second thin film transistor, and a hydrogen supply layer disposed to overlap the first thin film transistor, wherein the hydrogen supply layer does not overlap the second thin film transistor. Further, the present disclosure provides a display device using the above thin transistor substrate.

### BRIEF DESCRIPTION OF THE DRAWINGS

The features and other advantages of the present disclosure will be more clearly understood from the following detailed description taken in conjunction with the accompanying drawings, in which:

FIG. 1 is a schematic perspective view of a display device according to one embodiment of the present disclosure.

FIG. 2 is a plan view schematically showing a display device according to one embodiment of the present disclosure.

FIG. 3 is a plan view of a thin film transistor substrate according to one embodiment of the present disclosure.

FIG. 4 is a cross-sectional view of a thin film transistor substrate according to one embodiment of the present disclosure. In this case, FIG. 4 relates to cross sections I-I′ and II-II′ of FIG. 2.

FIGS. 5A to 5D are process cross-sectional views of a thin film transistor substrate according to one embodiment of the present disclosure. In this case, FIGS. 5A to 5D relate to cross-sections I-I′ and II-II′ of FIG. 2.

FIG. 6 is a cross-sectional view of a thin film transistor substrate according to another embodiment of the present disclosure. In this case, FIG. 6 relates to cross sections I-I′ and II-II′ of FIG. 2.

FIGS. 7A to 7F are process cross-sectional views of a thin film transistor substrate according to another embodiment of the present disclosure. In this case, FIGS. 7A to 7F relate to cross-sections I-I′ and II-II′ of FIG. 2.

FIG. 8 is a cross-sectional view of a thin film transistor substrate according to another embodiment of the present disclosure. In this case, FIG. 8 is related to cross-section II-II′ of FIG. 2.

FIG. 9 is a cross-sectional view of a display device including a thin film transistor substrate according to one embodiment of the present disclosure.

FIG. 10 is a circuit diagram of one pixel disposed in a display device according to one embodiment of the present disclosure.

FIG. 11 is a circuit diagram of a shift register according to one embodiment of the present disclosure.

### DETAILED DESCRIPTION OF THE EMBODIMENTS

The advantages and features of the present disclosure, and the methods for achieving them, will become clear with reference to the embodiments described in detail below together with the accompanying drawings. However, the present disclosure is not limited to the embodiments disclosed below, but can be implemented in various different forms, and these embodiments are disposed only to make the disclosure of the present disclosure complete and to fully inform a person having ordinary skill in the art to which the present disclosure belongs of the scope of the invention, and the present disclosure is defined only by the scope of the claims.

The shapes, sizes, ratios, angles, numbers, or the like disclosed in the drawings for explaining embodiments of the present disclosure are examples, and therefore the present disclosure is not limited to the matters illustrated. Like reference numerals refer to like elements throughout the disclosure. In addition, in describing the present disclosure, if it is determined that a detailed description of a related known technology can unnecessarily obscure the gist of the present disclosure, the detailed description will be omitted. When the terms “includes,” “has,” “consists of,” or the like are used in this disclosure, other parts can be added unless “only” is used. When a component is expressed in the singular, it includes a case where the plural is included unless there is a specifically explicit description.

When interpreting a component, it is interpreted as including the error range even if there is no separate explicit description of the error range.

When describing a positional relationship, for example, when the positional relationship between two parts is described as ‘on ˜’, ‘upper ˜’, ‘lower ˜’, ‘next to ˜’, or the like, one or more other parts can be located between the two parts, unless ‘right’ or ‘directly’ is used.

When describing a temporal relationship, for example, when describing a temporal relationship using phrases such as ‘after’, ‘following’, ‘next to’, or ‘before’, it can also include cases where there is no continuity, as long as ‘right away’ or ‘directly’ is not used. The term “can” fully encompasses all the meanings and coverages of the term “may.”

Although the terms such as “first”, “second”, or the like are used to describe various components, these components are not limited by these terms. These terms are only used to distinguish one component from another. Accordingly, a first component referred to below can also be a second component within the technical concept of the present disclosure.

The individual features of the various embodiments of the present disclosure can be partially or wholly combined with each other, and can be technically linked and driven in various ways, and each embodiment can be implemented independently of each other or can be implemented together in a related relationship.

Hereinafter, preferred embodiments of the present disclosure will be described in detail with reference to the drawings.

FIG. 1 is a schematic perspective view of a display device according to one embodiment of the present disclosure.

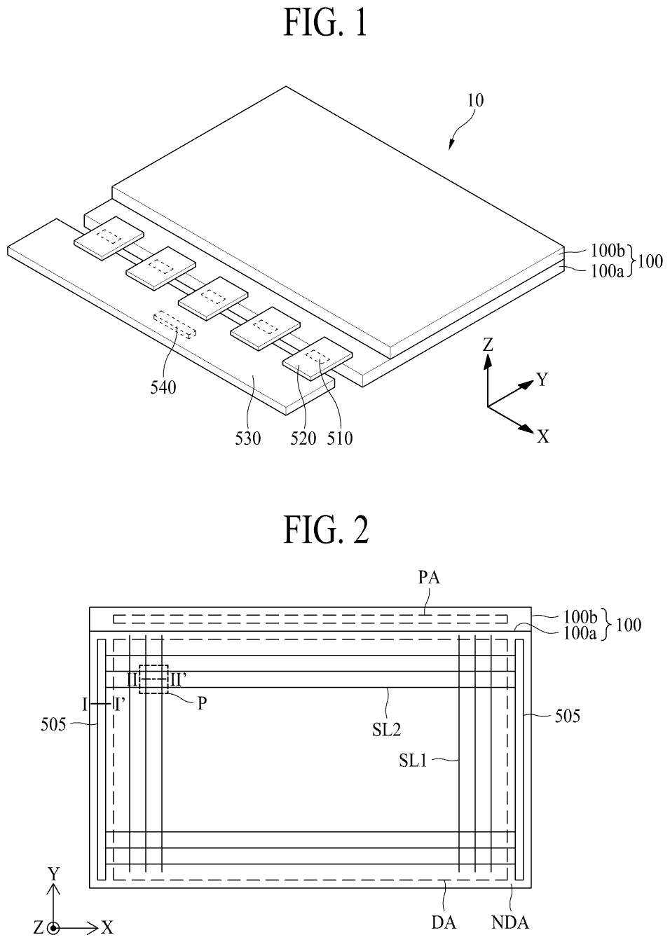

FIG. 2 is a plan view schematically showing a display device according to one embodiment of the present disclosure. All components of a display device according to all embodiments of the present disclosure are operatively coupled and configured.

Hereinafter, the X-axis represents a direction parallel to the gate line, the Y-axis represents a direction parallel to the data line, and the Z-axis represents the height direction of the display device 10.

The display device 10 according to one embodiment of the present disclosure has been described mainly as being implemented as an organic light emitting display, but can also be implemented as a liquid crystal display, a plasma display panel (PDP), a quantum dot light emitting display (QLED), or an electrophoresis display.

Referring to FIGS. 1 and 2, a display device 10 according to one embodiment of the present disclosure includes a display panel 100, a source drive integrated circuit (hereinafter referred to as “IC”) 510, a flexible film 520, a circuit board 530, and a timing control unit 540.

The display panel 100 includes the first substrate 100a and the second substrate 100b facing each other. The second substrate 100b can be a sealing substrate. The first substrate 100a can be made of a plastic film, a glass substrate, or a silicon wafer substrate formed using a semiconductor process. The second substrate 100b can be a plastic film, a glass substrate, or a sealing film. The first substrate 100a and the second substrate 100b can be made of a transparent material.

The display panel 100 can be divided into a display area DA where pixels are formed to display an image and a non-display area NDA where no image is displayed.

The display area DA can be provided with a plurality of vertical signal lines SL1, a plurality of horizontal signal lines SL2, and a plurality of pixels P, and the non-display area NDA can be provided with a pad area PA in which pads are arranged and at least one gate driver 505. Meanwhile, FIG. 2 illustrates a state in which one gate driver 505 is disposed on each of a one side and the other side of the display panel 100, but is not limited thereto.

The plurality of vertical signal lines SL1 can extend in a first direction (Y-axis direction) and can intersect the plurality of horizontal signal lines SL2 in the display area DA. The plurality of vertical signal lines SL1 can be, for example, a high-potential voltage line supplying a high-potential voltage to an anode electrode, a reference voltage line transmitting a reference signal to each of the plurality of pixels P, a data line transmitting a data signal to each of the plurality of pixels P, or the like, but are not limited thereto, and according to the level of technology in the art, the plurality of vertical signal lines SL1 can be one of various wirings transmitting signals.

The plurality of horizontal signal lines SL2 can extend in a second direction (X-axis direction) in the display area DA. The plurality of horizontal signal lines SL2 can be, for example, gate lines that transmit gate signals to each of the plurality of pixels P, but are not limited thereto, and according to the level of technology in the art, the plurality of horizontal signal lines SL2 can be one of various wirings that transmit signals.

The plurality of pixels P are disposed in an area where the plurality of first signal lines SL1 are provided or in an area where the plurality of first signal lines SL1 and the plurality of second signal lines SL2 intersect, and emit a predetermined amount of light to display an image.

The source drive IC 510 receives digital video data and a source control signal from the timing control unit 540. The source drive IC 510 converts digital video data into analog data voltages according to the source control signal and supplies the converted data to the data line. When the source drive IC 510 is manufactured as a driving chip, it can be mounted on the flexible film 520 in a COF (chip on film) or COP (chip on plastic) method.

Wires connecting the pads and the source drive IC 510, and wires connecting the pads and the wires of the circuit board 530 can be disposed on the flexible film 520. The flexible film 520 is attached onto the pads using an anisotropic conducting film, thereby connecting the pads and the wires of the flexible film 520.

The circuit board 530 can be attached to the flexible films 520. The circuit board 530 can have a plurality of circuits implemented with driving chips mounted thereon. For example, the timing control unit 540 can be mounted on the circuit board 530. The circuit board 530 can be a printed circuit board or a flexible printed circuit board. But embodiments of the present disclosure are not limited thereto.

The timing control unit 540 receives digital video data and a timing signal from an external system board. The timing control unit 540 generates a gate control signal for controlling the operation timing of the gate driver based on the timing signal and a source control signal for controlling the source drive ICs 510. The timing control unit 540 supplies the gate control signal to the gate driver 505 and the source control signal to the source drive ICs 510.

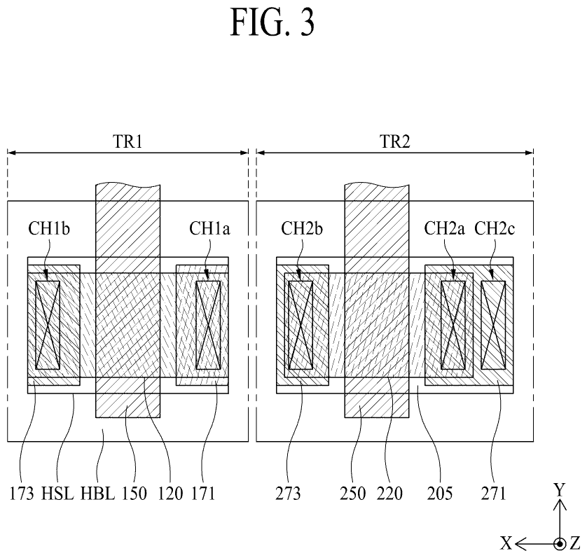

FIG. 3 is a plan view of a thin film transistor substrate according to one embodiment of the present disclosure.

As can be seen in FIG. 3, a thin film transistor substrate according to one embodiment of the present disclosure includes a first thin film transistor TR1, a second thin film transistor TR2, a hydrogen supply layer HSL, and a hydrogen barrier layer HBL.

As an example, the first thin film transistor TR1 can be disposed in, for example, the non-display area (see NDA of FIG. 2), and the second thin film transistor TR2 can be disposed in, for example, the display area (see DA of FIG. 2). In detail, the first thin film transistor TR1 can be disposed in, for example, the gate driver (see 505 of FIG. 2) in the non-display area NDA, and the second thin film transistor TR2 can be, for example, a driving thin film transistor Tdr or a switching thin film transistor Tsw in the display area DA, but is not limited thereto.

As another example, the first thin film transistor TR1 and the second thin film transistor TR2 can be disposed in the display area DA. In this case, the first thin film transistor TR1 can constitute the switching thin film transistor Tsw, and the second thin film transistor TR2 can constitute the driving thin film transistor Tdr, but is not limited thereto.

The first thin film transistor TR1 is composed of a first active layer 120, a first gate electrode 150, a first source electrode 171, and a first drain electrode 173.

The first active layer 120 can extend in a first direction X, for example, in the horizontal direction.

The first gate electrode 150 can extend in a second direction Y, for example, a vertical direction. The first gate electrode 150 can overlap a portion of the first active layer 120.

The first source electrode 171 can be disposed on one side of the first active layer 120, for example, on the right side. The first source electrode 171 can be electrically connected to one side of the first active layer 120 through the 1-1 contact hole CH1a.

The first drain electrode 173 can be disposed on the other side of the first active layer 120, for example, on the left side. The first drain electrode 173 can be electrically connected to the other side of the first active layer 120 through the 1-2 contact hole CH1b.

The second thin film transistor TR2 is composed of a light blocking layer 205, a second active layer 220, a second gate electrode 250, a second source electrode 271, and a second drain electrode 273.

The second active layer 220 can extend in a first direction X, for example, in a horizontal direction.

The second gate electrode 250 can extend in a second direction Y, for example, a vertical direction. The second gate electrode 250 can overlap a portion of the second active layer 220.

The second source electrode 271 can be disposed on one side of the second active layer 220, for example, on the right side. The second source electrode 271 can be electrically connected to one side of the second active layer 220 through the 2-1 contact hole CH2a.

The second drain electrode 273 can be disposed on the other side of the second active layer 220, for example, on the right side. The second drain electrode 273 can be electrically connected to the other side of the second active layer 220 through the 2-2 contact hole CH2b.

The above described light blocking layer 205 can extend in the first direction X, for example, in the horizontal direction. The light blocking layer 205 can overlap the second active layer 220 to prevent light from the outside from reaching the second active layer 220.

The above described light blocking layer 205 can be electrically connected to the second source electrode 171 through the 2-3 contact hole CH2c.

According to one embodiment of the present disclosure, the hydrogen supply layer HSL can be formed in an area where the first thin film transistor TR1 is formed. In detail, the hydrogen supply layer HSL can be formed to overlap the first active layer 120 of the first thin film transistor TR1. The hydrogen supply layer HSL can supply hydrogen to the first active layer 120.

The hydrogen supply layer HSL can be patterned to correspond to the area where the first thin film transistor TR1 is formed so as not to be formed in the area where the second thin film transistor TR2 is formed. Accordingly, hydrogen supplied from the hydrogen supply layer HSL can diffuse into the first thin film transistor TR1 where the hydrogen supply layer HSL is formed, but hydrogen is not supplied from the hydrogen supply layer HSL to the second thin film transistor TR2 where the hydrogen supply layer HSL is not formed.

According to one embodiment of the present disclosure, the hydrogen barrier layer HBL can be formed in an area where the first thin film transistor TR1 and the second thin film transistor TR2 are formed. In detail, the hydrogen barrier layer HBL can be formed to overlap the first active layer 120 of the first thin film transistor TR1 and to overlap the second active layer 220 of the second thin film transistor TR2.

As can be seen in FIG. 3, an area of the hydrogen supply layer HSL can correspond to an area covered by the first active layer 120, and can include an area of the first drain electrode 173, at least a portion the first gate electrode 150, an area of the first source electrode 171, and areas in between the first drain electrode 173, the first gate electrode 150, and the first source electrode 171. Meanwhile, an area of the hydrogen barrier layer HBL can be different from the area of the hydrogen supply layer HSL. For example, the area of the hydrogen barrier layer HBL can be greater than the area of the hydrogen supply layer HSL.

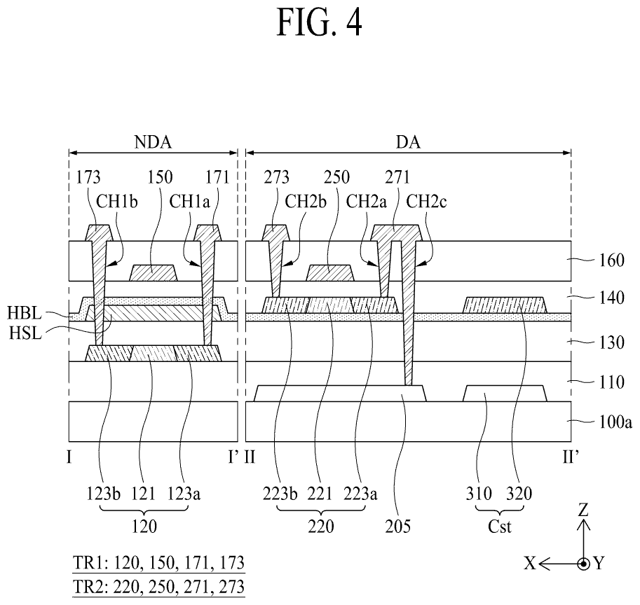

FIG. 4 is a cross-sectional view of a thin film transistor substrate according to one embodiment of the present disclosure. In this case, FIG. 4 relates to cross sections I-I′ and II-II′ of FIG. 2.

As can be seen in FIG. 4, a thin film transistor substrate according to one embodiment of the present disclosure includes a first substrate 100a, a buffer layer 110, a first thin film transistor TR1, a second thin film transistor TR2, a storage capacitor Cst, a first gate insulating layer 130, a hydrogen supply layer HSL, a hydrogen barrier layer HBL, a second gate insulating layer 140, and an interlayer insulating layer 160.

The first substrate 100a can be made of glass or plastic. In particular, the first substrate 100a can be made of a transparent plastic having flexible property, for example, polyimide. When polyimide is used as the first substrate 100a, considering that a high-temperature deposition process is performed on the first substrate 100a, a heat-resistant polyimide that can withstand high temperatures can be used. But embodiments of the present disclosure are not limited thereto.

The buffer layer 110 is disposed on the first substrate 100a. The buffer layer 110 can protect the first active layer 120 by blocking air and moisture. The buffer layer 110 can be formed of an inorganic insulating material such as silicon oxide, silicon nitride, or metal oxide, but is not necessarily limited thereto and can be formed of an organic insulating material. The buffer layer 110 can be formed of a single layer or can be formed of a plurality of layers.

The first thin film transistor TR1 can be formed in the non-display area NDA. For example, the first thin film transistor TR1 can be any one of a plurality of thin film transistors disposed in a gate driver (see 505 of FIG. 2) disposed in the non-display area NDA.

The first thin film transistor TR1 can be disposed on the buffer layer 110. In detail, the first thin film transistor TR1 includes a first active layer 120, a first gate electrode 150, a first source electrode 171, and a first drain electrode 173. In this case, the first active layer 120 can be disposed on the buffer layer 110, the first gate electrode 150 can be disposed on the second gate insulating layer 140, and the first source electrode 171 and the first drain electrode 173 can be disposed on the interlayer insulating layer 160.

The first active layer 120 can be formed of a semiconductor material. In detail, the first active layer 120 can be formed of a semiconductor material containing polycrystalline silicon p-Si. In detail, the first active layer 120 can be formed of a semiconductor material containing low-temperature polycrystalline silicon (LTPS).

The first active layer 120 can include a first channel part 121, a first connection part 123a, and a second connection part 123b. The first connection part 123a and the second connection part 123b can be formed by a conductorizing process for a semiconductor material containing silicon. For example, the first connection part 123a and the second connection part 123b can be formed by conductorizing a portion of the first active layer 120 using the first gate electrode 150 as a mask. In this case, the conductorizing process can be performed by doping a portion of the first active layer 120 containing silicon with a group III (or group XIII) element or a group V (or group XV) element. The first connection part 123a and the second connection part 123b can have superior conductive property compared to the first channel part 121 and can be used as wiring or source/drain electrodes.

The first gate insulating layer 130 can be disposed on the first active layer 120. In detail, the first gate insulating layer 130 can be disposed on the entire surface of the first substrate 100a and can be disposed on the first active layer 120 and the buffer layer 110. The first active layer 120 can be disposed in a form in which it is wrapped by the buffer layer 110 and the first gate insulating layer 130.

The first gate insulating layer 130 can include, but is not limited to, a silicon nitride film (SiNx) or a silicon oxide film (SiOx). The first gate insulating layer 130 can be formed of a single layer or multiple layers including an inorganic insulating material and/or an organic insulating material.

The hydrogen supply layer HSL can be disposed on the first gate insulating layer 130. According to one embodiment of the present disclosure, the hydrogen supply layer HSL can be disposed in a region where the first thin film transistor TR1 is formed. The hydrogen supply layer HSL can be disposed on the first active layer 120 so as to overlap with the first active layer 120 of the first thin film transistor TR1. Since the hydrogen supply layer HSL is disposed on the first active layer 120, a large amount of hydrogen contained in the hydrogen supply layer HSL can diffuse into the first active layer 120, and the silicon semiconductor material included in the first active layer 120 can be crystallized by the diffused hydrogen.

The hydrogen supply layer HSL can be disposed on the first gate insulating layer 130 by, for example, chemical vapor deposition CVD or plasma enhanced chemical vapor deposition PECVD, but is not limited thereto.

The hydrogen supply layer HSL can contain an excess of hydrogen. The amount of hydrogen contained in the hydrogen supply layer HSL can be greater than the amount of hydrogen contained in the first gate insulating layer 130. The amount of hydrogen contained in the hydrogen supply layer HSL can be greater than the amount of hydrogen contained in the second gate insulating layer 140. The amount of hydrogen contained in the hydrogen supply layer HSL can be greater than the amount of hydrogen contained in the hydrogen barrier layer HBL.

The hydrogen supply layer HSL can include, but is not limited to, silicon nitride (SiNx) formed by, for example, plasma enhanced chemical vapor deposition PECVD.

The hydrogen supply layer HSL can be formed with a thickness of 50 Å to 500 Å. If the hydrogen supply layer HSL is formed with a thickness of less than 50 Å, the hydrogen supply layer HSL may not be properly formed, and if the hydrogen supply layer HLS is formed with a thickness exceeding 500 Å, the characteristic of the device can change.

The hydrogen supply layer HSL can be provided so as to overlap the front surface of the first active layer 120. Accordingly, by being provided so as to cover the front surface of the first active layer 120, hydrogen contained in the hydrogen supply layer HSL can diffuse into the first active layer 120 during the process of forming a thin film transistor substrate according to an embodiment of the present disclosure, thereby improving the conductive property of the silicon semiconductor material contained in the first active layer 120.

The hydrogen barrier layer HBL can be disposed on the first gate insulating layer 130 and the hydrogen supply layer HSL.

The hydrogen barrier layer HBL can be disposed on the entire surface of the first substrate 100a. By being formed in this manner, hydrogen contained in part in the buffer layer 110 or the first gate insulating layer 130 can be prevented from flowing into the interior of the second active layer 220. Furthermore, the hydrogen barrier layer HBL can cover the upper surface of the hydrogen supply layer HSL, thereby preventing hydrogen diffused from the hydrogen supply layer HSL from diffusing into other areas except for the first active layer 120.

The hydrogen barrier layer HBL can be disposed on the first gate insulating layer 130 using, for example, atomic layer deposition ALD, plasma enhanced atomic layer deposition PEALD, or metal organic atomic layer deposition (MOALD). In this case, the metal organic atomic layer deposition (MOALD) can mean performing atomic layer deposition ALD using an organic metal as a precursor material.

The hydrogen barrier layer HBL may include, but is not limited to, for example, any of silicon oxide (SiO₂), aluminum oxide (Al₂O₃) and titanium oxide (TiO₂) formed by formed by the above metal organic atomic layer deposition (MOALD) method.

By forming the hydrogen barrier layer HBL by the metal-organic atomic layer deposition (MOALD), the hydrogen barrier layer HBL can be formed as a film having excellent film quality and relatively high density. By forming in this manner, the hydrogen content inside the hydrogen barrier layer HBL can be relatively low. For example, the amount of hydrogen contained inside the hydrogen barrier layer HBL can be less than the amount of hydrogen contained in the first gate insulating layer 130, the amount of hydrogen contained inside the hydrogen barrier layer HBL can be less than the amount of hydrogen contained in the second gate insulating layer 130, and the amount of hydrogen contained inside the hydrogen barrier layer HBL can be less than the amount of hydrogen contained inside the hydrogen supply layer HSL.

The thickness of the hydrogen barrier layer HBL can be thinner than the thickness of the first gate insulating layer 130. The thickness of the hydrogen barrier layer HBL can be thinner than the thickness of the second gate insulating layer 140. The thickness of the hydrogen barrier layer HBL can be thinner than the thickness of the second active layer 220.

According to one embodiment of the present disclosure, the hydrogen supply layer HBL is patterned to correspond to a region where the first thin film transistor TR1 is formed, and the hydrogen barrier layer HSL is formed without being separately patterned to overlap both the first thin film transistor TR1 and the second thin film transistor TR2, thereby enabling both the hydrogen supply layer HBL and the hydrogen barrier layer HSL to be formed without adding a separate mask.

The second gate insulating layer 140 can be disposed on the hydrogen barrier layer HBL. The second gate insulating layer 140 can include, but is not limited to, a silicon nitride film (SiNx) or a silicon oxide film (SiOx). The second gate insulating layer 140 can be formed of a single layer or multiple layers including an inorganic insulating material and/or an organic insulating material.

The first gate electrode 150 can be disposed on the second gate insulating layer 140. The first gate electrode 150 can be disposed on the first active layer 120. In detail, the first gate electrode 150 can overlap the first channel part 121 of the first active layer 120.

The first gate electrode 150 can include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The first gate electrode 150 can have a structure including one metal layer or a multilayer film structure including at least two metal layers each having different physical property.

The interlayer insulating layer 160 insulates between the first gate electrode 150 and the first source electrode 171, and further insulates between the first gate electrode 150 and the first drain electrode 173. The interlayer insulating layer 160 can be formed of a single layer or multiple layers including an inorganic insulating material and/or an organic insulating material.

The interlayer insulating layer 160 can be provided with a 1-1 contact hole CH1a and a 1-2 contact hole CH1b. Accordingly, a part of the upper surface of the first connection part 123a of the first active layer 120 can be exposed by the 1-1 contact hole CH1a. Furthermore, a part of the upper surface of the second connection part 123b of the first active layer 120 can be exposed by the 1-2 contact hole CH1b.

The first source electrode 171 and the first drain electrode 173 can be disposed on the interlayer insulating layer 160. The first source electrode 171 and the first drain electrode 173 can be formed of the same material as the gate electrode 150, but are not limited thereto and can be formed of a material according to knowledge in the art.

The first source electrode 171 can be electrically connected to one side of the first active layer 120, for example, the first connection part 123a, and the first drain electrode 173 can be electrically connected to the other side of the first active layer 120, for example, the second connection part 123b. In detail, the first source electrode 171 can be connected to the first connection part 123a of the first active layer 120 through the 1-1 contact hole CH1a disposed in the first gate insulating layer 130, the hydrogen supply layer HSL, the hydrogen barrier layer HBL, the second gate insulating layer 140, and the interlayer insulating layer 160, and the first drain electrode 173 can be connected to the second connection part 123b of the first active layer 120 through the 1-2 contact hole CH1b disposed in the first gate insulating layer 130, the hydrogen supply layer HSL, the hydrogen barrier layer HBL, the second gate insulating layer 140, and the interlayer insulating layer 160.

The second thin film transistor TR2 can be formed in the display area DA. For example, the second thin film transistor TR2 can be any one of a plurality of thin film transistors disposed in the display area DA and for driving pixels. For example, the second thin film transistor TR2 can be any one of a switching thin film transistor and a driving thin film transistor disposed in the display area DA, but is not limited thereto.

The second thin film transistor TR2 can be disposed on the first substrate 100a. In detail, the second thin film transistor TR2 can include the light blocking layer 205, the second active layer 220, the second gate electrode 250, the second source electrode 271, and the second drain electrode 273.

The light blocking layer 205 can be disposed on the first substrate 100a. The light blocking layer 205 can be formed of a metal or a metal oxide, and can be formed of one metal layer or metal oxide layer, or two or more metal layers or metal oxide layers.

The light blocking layer 205 is provided under the second active layer 220 and overlaps with the second active layer 220, thereby preventing light from the outside of the thin film transistor substrate from entering the second active layer 220. In detail, the light blocking layer 205 can prevent external light from entering the second channel part 221 of the second active layer 220. Meanwhile, a separate insulating layer can be additionally provided between the light blocking layer 205 and the first substrate 100a.

The second active layer 220 can be disposed on the hydrogen barrier layer HBL. According to one embodiment of the present disclosure, since the second active layer 220 is disposed on the hydrogen barrier layer HBL, a portion of hydrogen contained in the first gate insulating layer 130 can be prevented from flowing into the second active layer 220. Accordingly, a change in the device characteristic of the active layer 220 can be minimized, thereby implementing a highly reliable thin film transistor substrate.

The second active layer 220 can be formed of a semiconductor material, for example, an oxide semiconductor material. The oxide semiconductor material can include, for example, at least one of an IZO (InZnO) based oxide semiconductor material, an IGO (InGaO) based oxide semiconductor material, an ITO (InSnO) based oxide semiconductor material, an IGZO (InGaZnO) based oxide semiconductor material, an IGZTO (InGaZnSnO) based oxide semiconductor material, a GZTO (GaZnSnO) based oxide semiconductor material, a GZO (GaZnO) based oxide semiconductor material, an ITZO (InSnZnO) based oxide semiconductor material, and a FIZO (FeInZnO) based oxide semiconductor material. But embodiments of the present disclosure are not limited thereto.

The second active layer 220 comprises a second channel part 221, a first connection part 223a connected to one side of the second channel part 221, and a second connection part 223b connected to the other side of the second channel part 221. The first connection part 223a and the second connection part 223b can be provided with conductive property by a conductorizing process that performs ion doping or plasma treatment on a semiconductor material using the second gate electrode 250 as a mask.

The conductorizing process can be defined as a process of imparting conductive property to an oxide semiconductor material. An oxide semiconductor material that has undergone the conductorizing process can have conductive property. The conductorizing process can include, for example, a doping process using dopant ions and a plasma process of applying plasma to make it conductorized. Through the conductorizing process, a portion of the second active layer 220 can be conductorized and have conductive property. In this case, the first connection part 223a and the second connection part 223b can be conductorized and made to have conductive property by the conductorizing process, and the first connection part 223a and the second connection part 223b have greater conductivity compared to the second channel part 221, and each can also function as a wiring or a source/drain electrode.

The second gate electrode 250 can be disposed on the second gate insulating layer 140. The second gate electrode 250 can be disposed on the second active layer 220. In detail, the second gate electrode 250 can overlap the second channel part 221 of the second active layer 220.

The second gate electrode 250 can be formed using the same material in the same layer as the first gate electrode 150, but is not limited thereto.

The second gate electrode 250 can include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The second gate electrode 250 can have a structure including one metal layer or a multilayer film structure including at least two metal layers each having different physical property. But embodiments of the present disclosure are not limited thereto.

The interlayer insulating layer 160 can be provided with a 2-1 contact hole CH2a, a 2-2 contact hole CH2b, and a 2-3 contact hole CH2c. Accordingly, a part of the upper surface of the first connection part 223a of the second active layer 220 can be exposed by the 2-1 contact hole CH2a. Furthermore, a part of the upper surface of the second connection part 223b of the second active layer 220 can be exposed by the 2-2 contact hole CH2b. A part of the upper surface of the light blocking layer 205 can be exposed by the 2-3 contact hole CH2c.

The second source electrode 271 and the second drain electrode 273 can be disposed on the interlayer insulating layer 160. The second source electrode 271 and the second drain electrode 273 can be formed of the same material as the second gate electrode 250, but are not limited thereto and can be formed of a material according to knowledge in the art.

The second source electrode 271 can be electrically connected to one side of the second active layer 220, for example, the first connection part 223a, and the second drain electrode 273 can be electrically connected to the other side of the second active layer 220, for example, the second connection part 223b. In detail, the second source electrode 271 can be connected to the first connection part 223a of the second active layer 220 through the 2-1 contact hole CH2a disposed in the second gate insulating layer 140 and the interlayer insulating layer 160, and the second drain electrode 273 can be connected to the second connection part 223b of the second active layer 220 through the 2-2 contact hole CH2b disposed in the second gate insulating layer 140 and the interlayer insulating layer 160.

The second source electrode 271 can be electrically connected to the light blocking layer 205 through the 2-3 contact hole CH2c disposed in the buffer layer 110, the first gate insulating layer 130, the hydrogen barrier layer HBL, the second gate insulating layer 140, and the interlayer insulating layer 160.

According to one embodiment of the present disclosure, the first thin film transistor TR1 constitutes one thin film transistor among a plurality of thin film transistors of the gate driver (see 505 of FIG. 2) disposed in the non-display area NDA, and the second thin film transistor TR2 constitutes one thin film transistor among a plurality of thin film transistors disposed in the display area DA and for driving the pixel, thereby implementing a thin film transistor disposed in the gate driver (see 505 of FIG. 2) having high on-current characteristic, and implementing a thin film transistor disposed in the pixel with improved reliability of the device.

The storage capacitor Cst can be formed, for example, on the first substrate 100a. In detail, the storage capacitor Cst includes a first capacitor electrode 310 and a second capacitor electrode 320.

The first capacitor electrode 310 can be disposed on the first substrate 100a. The first capacitor electrode 310 can be formed, for example, using the same material in the same layer as the light blocking layer 205, but is not limited thereto.

The second capacitor electrode 320 can be disposed on the hydrogen barrier layer HBL. In this case, the second capacitor electrode 320 can be formed using the same material as the second active layer 220 in the same layer. When the second capacitor electrode 320 is formed using the same material as the second active layer 220, conductive property can be imparted to the second capacitor electrode 320 through the conductorizing process. Meanwhile, the present disclosure is not limited thereto, and the second capacitor electrode 320 can be formed as an electrode having conductive property by including a metal material.

The charges can be charged to the storage capacitor Cst by the first capacitor electrode 310, the second capacitor electrode 320, and the buffer layer 110, the first gate insulating layer 130, and the hydrogen barrier layer HBL provided between the first capacitor electrode 310 and the second capacitor electrode 320.

According to one embodiment of the present disclosure, by forming the thickness of the hydrogen barrier layer HBL to be thinner than the thickness of the first gate insulating layer 130, the second gate insulating layer 140, or the second active layer 220, the distance between the first capacitor electrode 310 and the second capacitor electrode 320 may not be significantly changed. Accordingly, even though the hydrogen barrier layer HBL is provided, the storage voltage charged to the storage capacitor Cst may not be significantly changed.

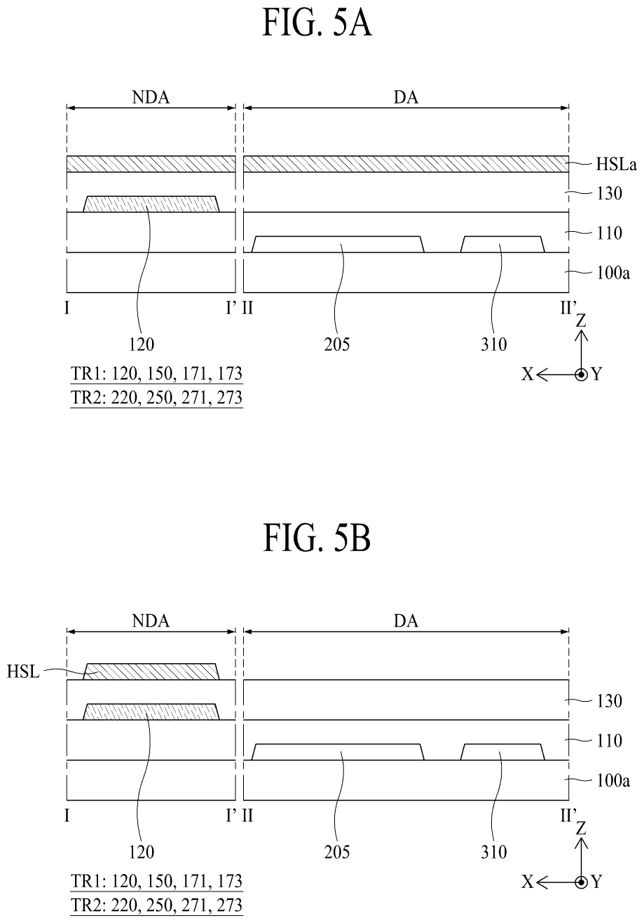

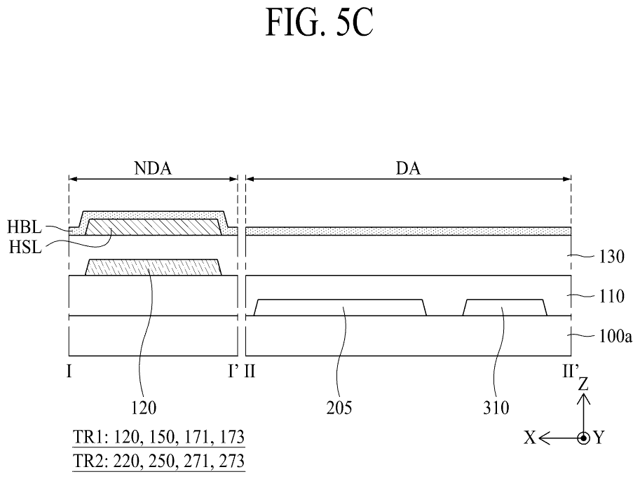

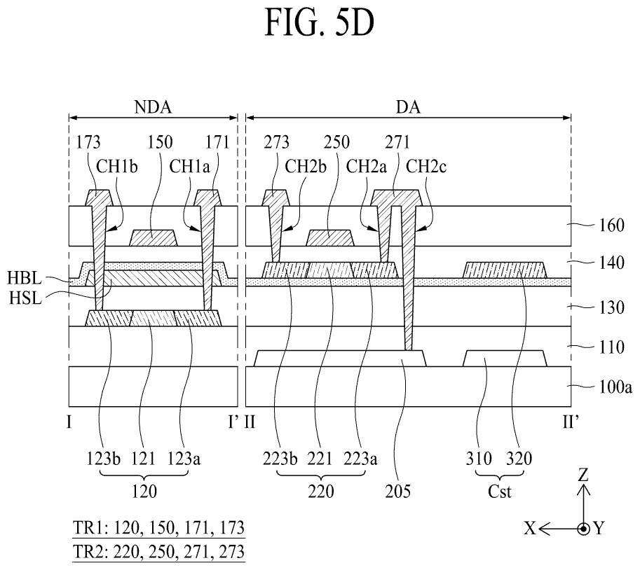

FIGS. 5A to 5D are process cross-sectional views of a thin film transistor substrate according to one embodiment of the present disclosure. In this case, FIGS. 5A to 5D relate to cross-sections I-I′ and II-II′ of FIG. 2. Meanwhile, since the embodiments of FIGS. 5A to 5D are identical to the embodiments of FIG. 4, identical components are given the same reference numerals and repeated descriptions are omitted.

First, as can be seen in FIG. 5A, the light blocking layer 205 of the second thin film transistor TR2 and the first capacitor electrode 310 of the storage capacitor Cst can be patterned on the first substrate 100a. In this case, the light blocking layer 205 and the first capacitor electrode 310 can be formed using the same material in the same process, but are not limited thereto.

Furthermore, the buffer layer 110 can be disposed on the light blocking layer 205 and the first capacitor electrode 310, the first active layer 120 of the first thin film transistor TR1 can be pattern-formed, and the first gate insulating layer 130 can be disposed on the buffer layer 110 and the first active layer 120.

In addition, a hydrogen supply material layer HSLa can be disposed on the first gate insulating layer 130. The hydrogen supply material layer HSLa can be formed, for example, through a chemical vapor deposition method CVD or a plasma enhanced chemical vapor deposition method (PECVD). However, the present disclosure is not limited thereto.

The hydrogen supply material layer HSLa can include, but is not limited to, silicon nitride (SiNx) formed by, for example, plasma enhanced chemical vapor deposition (PECVD).

The hydrogen supply material layer HSLa can be formed with a thickness of 50 Å to 500 Å. If the hydrogen supply material layer HSLa is formed with a thickness of less than 50 Å, the hydrogen supply material layer HSLa may not be properly formed, and if the hydrogen supply material layer HSLa is formed with a thickness exceeding 500 Å, the characteristic of the device can change.

Next, as can be seen in FIG. 5B, the hydrogen supply material layer HSLa can be patterned to form the hydrogen supply layer HSL. According to one embodiment of the present disclosure, the hydrogen supply layer HSL can be patterned to overlap the first active layer 120 of the first thin film transistor TR1. By forming in this manner, an excess of hydrogen contained in the hydrogen supply layer HSL is supplied to the first active layer 120, so that hydrogen can be bonded to unbonded sites in the low-temperature polycrystalline silicon, thereby improving crystallinity, and thus improving the mobility of the first thin film transistor TR1.

Next, as can be seen in FIG. 5C, the hydrogen barrier layer HBL can be disposed on the first gate insulating layer 130 and the hydrogen supply layer HSL. The hydrogen barrier layer HBL can be disposed on the entire surface of the first substrate 100a.

The hydrogen barrier layer HBL can be formed using, for example, atomic layer deposition (ALD), plasma enhanced atomic layer deposition (PEALD), or metal organic atomic layer deposition (MOALD). But embodiments of the present disclosure are not limited thereto.

The hydrogen barrier layer HBL may include, but is not limited to, for example, any of silicon oxide (SiO₂), aluminum oxide (Al₂O₃) and titanium oxide (TiO₂) formed by the above metal organic atomic layer deposition (MOALD) method.

By forming the above hydrogen barrier layer HBL by the above metal organic atomic layer deposition (MOALD), the hydrogen barrier layer HBL can be formed as a film having excellent film quality and relatively high density. By forming it in this way, the hydrogen content inside the hydrogen barrier layer HBL can be relatively low.

Further, as can be seen in FIG. 5D, the second active layer 220 of the second thin film transistor TR2 and the second capacitor electrode 320 of the storage capacitor Cst can be patterned on the hydrogen barrier layer HBL. In this case, the second active layer 220 and the second capacitor electrode 320 can be formed using the same material in the same process, but are not limited thereto.

In addition, the second gate insulating layer 140 can be disposed on the hydrogen barrier layer HBL, the second active layer 220, and the second capacitor electrode 320, and the first gate electrode 150 and the second gate electrode 250 can be disposed on the second gate insulating layer 140. In this case, the first gate electrode 150 and the second gate electrode 250 can be formed using the same material in the same process, but are not limited thereto. Furthermore, by performing a conductorizing process using each of the first gate electrode 150 and the second gate electrode 250 as a mask, the first channel part 121, the first connection part 123a, and the second connection part 123b can be formed in the first active layer 120, and the second channel part 221, the first connection part 223a, and the second connection part 223b can be formed in the second active layer 220.

The interlayer insulating layer 160 is disposed on the first gate electrode 150 and the second gate electrode 250, and the first source electrode 171, the first drain electrode 173, the second source electrode 271, and the second drain electrode 273 can be disposed on the interlayer insulating layer 160. In this case, the first source electrode 171, the first drain electrode 173, the second source electrode 271, and the second drain electrode 273 can be formed using the same material in the same process, but are not limited thereto.

With reference to the figures, including FIGS. 4-5D, the first drain electrode 173 and the first source electrode 171 can pass through the hydrogen barrier layer HBL and the hydrogen supply layer HSL But embodiments of the present disclosure are not limited thereto, and the first drain electrode 173 and the first source electrode 171 can pass through the hydrogen barrier layer HBL but can be arranged to not pass through the hydrogen supply layer HSL. For example, a size of the first active layer 120 can be made greater than a size of the hydrogen supply layer HSL layer so that outer peripheries of the second connection part 123b and the first connection part 123a are not overlapped by the hydrogen supply layer HSL, and the second connection part 123b is connected to the first drain electrode 173 and the first connection part 123a is connected to the first source electrode 171 without the first drain electrode 173 and the first source electrode 171 passing through the hydrogen supply layer HSL. Also, the hydrogen supply layer HSL can be patterned so that internal portions of the hydrogen supply layer HSL where the first drain electrode 173 and the first source electrode 171 are to pass through are without a portion of the hydrogen supply layer HSL.

In another embodiment of the present disclosure, the hydrogen supply material layer HSLa can be entirely removed during patterning operation once a sufficient amount of hydrogen is infused into the underlying first gate insulating layer 130 to provide sufficient amount of hydrogen can diffuse into the first active layer 120, and the silicon semiconductor material included in the first active layer 120 can be crystallized by the diffused hydrogen. When the hydrogen supply material layer HSLa is to be entirely removed, an area of the first gate insulating layer 130 overlapping the first active layer 120 can be preferentially be heated by light through photolithography or by a laser to increase adsorption or diffusion of hydrogen from the hydrogen supply material layer HSLa into the area of the first gate insulating layer 130 overlapping the first active layer 120.

In other embodiments of the present disclosure, the hydrogen supply material layer HSLa can be maintained without removal or patterning to reduce a process step of pattering or removing the hydrogen supply material layer HSLa.

With reference to FIGS. 4-5D, the hydrogen barrier layer HBL provides a platform whereby the lowest surface or a bottom surface of the second active layer 220 is raised above the first gate insulating layer 130. Accordingly, the lowest surface or the bottom surface of the second active layer 220 is located higher than the lowest surface or a bottom surface of the hydrogen supply layer HSL.

In various embodiments of the present disclosure, materials of the hydrogen supply layer HSL, the first gate insulating layer 130 and/or the second gate insulating layer 140 can be the same, while a material of the hydrogen supply layer HBL can be different from those of the hydrogen supply layer HSL, the first gate insulating layer 130 and/or the second gate insulating layer 140.

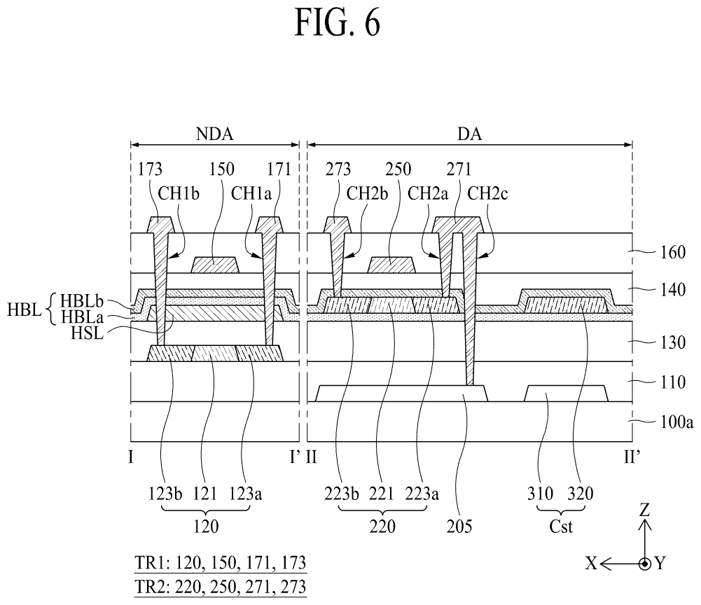

FIG. 6 is a cross-sectional view of a thin film transistor substrate according to another embodiment of the present disclosure. In this case, FIG. 6 relates to cross sections I-I′ and II-II′ of FIG. 2. Meanwhile, the embodiment of FIG. 6 is identical to the embodiment of FIG. 4 except for the configuration of the hydrogen barrier layer, so the following description will focus on the different configuration.

As can be seen in FIG. 6, a thin film transistor substrate according to another embodiment of the present disclosure includes a first substrate 100a, a buffer layer 110, a first thin film transistor TR1, a second thin film transistor TR2, a storage capacitor Cst, a first gate insulating layer 130, a hydrogen supply layer HSL, a hydrogen barrier layer HBL, a second gate insulating layer 140, and an interlayer insulating layer 160.

According to another embodiment of the present disclosure, the hydrogen barrier layer HBL comprises a first hydrogen barrier layer HBLa and a second hydrogen barrier layer HBLb.

The first hydrogen barrier layer HBLa and the second hydrogen barrier layer HBLb can be disposed on the entire surface of the first substrate 100a.

The first hydrogen barrier layer HBLa can be disposed on the first gate insulating layer 130 and the hydrogen supply layer HSL.

The first hydrogen barrier layer HBLa can be disposed on the entire surface of the first substrate 100a. By being formed in this manner, hydrogen contained in part in the buffer layer 110 or the first gate insulating layer 130 can be prevented from flowing into the interior of the second active layer 220. Furthermore, the first hydrogen barrier layer HBLa can cover the upper surface of the hydrogen supply layer HSL, thereby preventing hydrogen diffused from the hydrogen supply layer HSL from diffusing into other areas except for the first active layer 120.

The first hydrogen barrier layer HBLa can be disposed on the first gate insulating layer 130 using, for example, atomic layer deposition (ALD), plasma enhanced atomic layer deposition PEALD, or metal organic atomic layer deposition (MOALD). In this case, the metal organic atomic layer deposition (MOALD) can mean performing atomic layer deposition (ALD) using an organic metal as a precursor material.

The first hydrogen barrier layer HBLa may include, but is not limited to, for example, any of silicon oxide (SiO₂), aluminum oxide (Al₂O₃) and titanium oxide (TiO₂) formed by the above metal organic atomic layer deposition (MOALD) method.

By forming the first hydrogen barrier layer HBLa by the metal organic atomic layer deposition (MOALD), the first hydrogen barrier layer HBLa can be formed as a film having excellent film quality and relatively high density. By forming the first hydrogen barrier layer HBLa in this way, the hydrogen content inside the first hydrogen barrier layer HBLa can be relatively low. For example, the amount of hydrogen contained inside the first hydrogen barrier layer HBLa can be less than the amount of hydrogen contained in the first gate insulating layer 130, the amount of hydrogen contained inside the first hydrogen barrier layer HBLa can be less than the amount of hydrogen contained in the second gate insulating layer 140, and the amount of hydrogen contained inside the first hydrogen barrier layer HBLa can be less than the amount of hydrogen contained inside the hydrogen supply layer HSL. But embodiments of the present disclosure are not limited thereto.

The thickness of the first hydrogen barrier layer HBLa can be thinner than the thickness of the first gate insulating layer 130. The thickness of the first hydrogen barrier layer HBLa can be thinner than the thickness of the second gate insulating layer 140. The thickness of the first hydrogen barrier layer HBLa can be thinner than the thickness of the second active layer 220. But embodiments of the present disclosure are not limited thereto.

The second hydrogen barrier layer HBLb can be disposed on the first hydrogen barrier layer HBLa, the second active layer 220 of the second thin film transistor TR2, and the second capacitor electrode 320 of the storage capacitor Cst.

The second hydrogen barrier layer HBLb can be disposed on the entire surface of the first substrate 100a. By being formed in this manner, it is possible to prevent hydrogen contained in part in the second gate insulating layer 140 from flowing into the interior of the second active layer 220.

The second hydrogen barrier layer HBLb can be disposed on the first hydrogen barrier layer HBLa by, for example, atomic layer deposition (ALD), plasma enhanced atomic layer deposition (PEALD), or metal organic atomic layer deposition (MOALD). In this case, the metal organic atomic layer deposition (MOALD) can mean performing atomic layer deposition (ALD) using an organic metal as a precursor material.

The second hydrogen barrier layer HBLb may include, but is not limited to, for example, any of silicon oxide (SiO₂), aluminum oxide (Al₂O₃) and titanium oxide (TiO₂) formed by the above metal organic atomic layer deposition (MOALD) method.

By forming the second hydrogen barrier layer HBLb by the organic metal atomic layer deposition (MOALD), the second hydrogen barrier layer HBLb can be formed as a film having excellent film quality and relatively high density. By forming in this manner, the hydrogen content inside the second hydrogen barrier layer HBLb can be relatively low. For example, the amount of hydrogen contained inside the second hydrogen barrier layer HBLb can be less than the amount of hydrogen contained in the first gate insulating layer 130, the amount of hydrogen contained inside the second hydrogen barrier layer HBLb can be less than the amount of hydrogen contained in the second gate insulating layer 140, and the amount of hydrogen contained inside the second hydrogen barrier layer HBLb can be less than the amount of hydrogen contained inside the hydrogen supply layer HSL. But embodiments of the present disclosure are not limited thereto.

The thickness of the second hydrogen barrier layer HBLb can be thinner than the thickness of the first gate insulating layer 130. The thickness of the second hydrogen barrier layer HBLb can be thinner than the thickness of the second gate insulating layer 140. The thickness of the second hydrogen barrier layer HBLb can be thinner than the thickness of the second active layer 220. But embodiments of the present disclosure are not limited thereto.

According to one embodiment of the present disclosure, the hydrogen supply layer HBL is patterned to correspond to a region where the first thin film transistor TR1 is formed, and the hydrogen barrier layer HSL is formed without being separately patterned to overlap both the first thin film transistor TR1 and the second thin film transistor TR2, thereby enabling both the hydrogen supply layer HBL and the hydrogen barrier layer HSL to be formed without adding a separate mask.

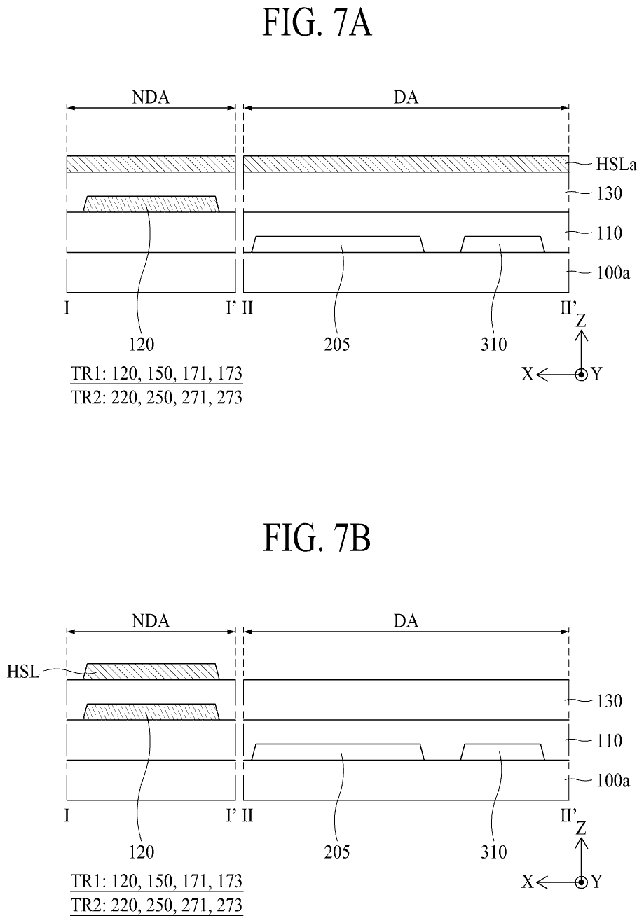

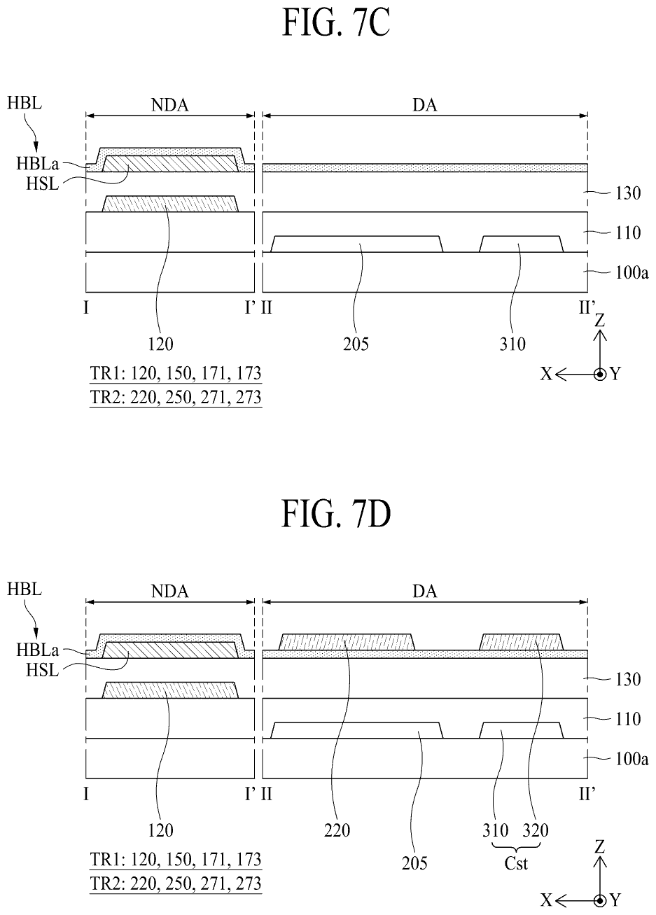

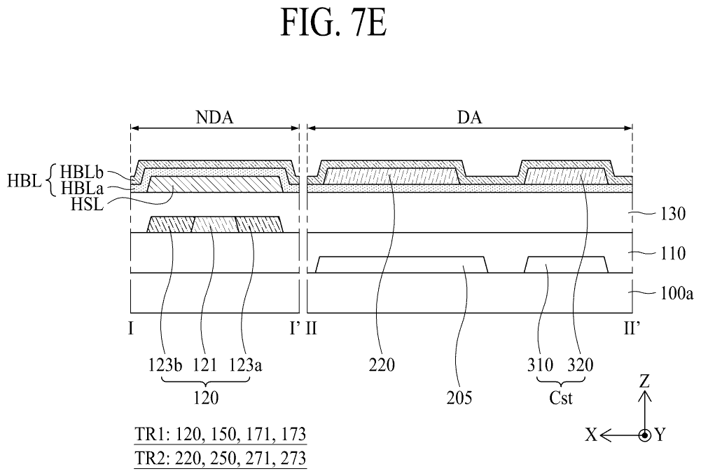

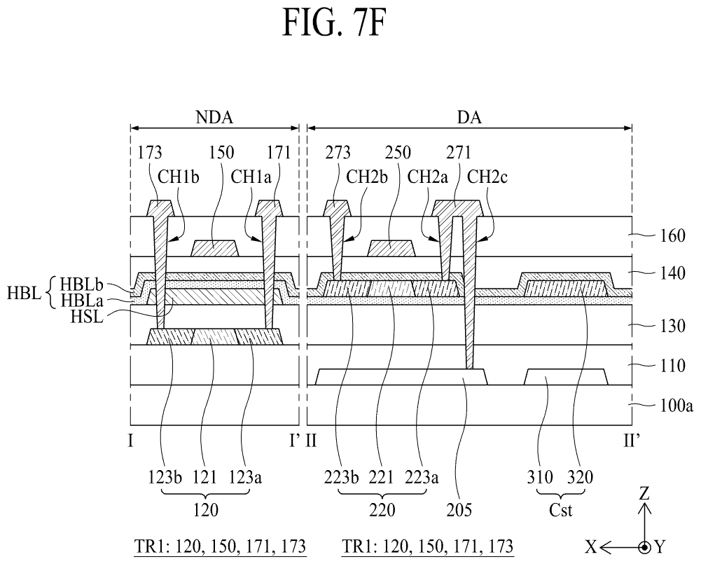

FIGS. 7A to 7F are process cross-sectional views of a thin film transistor substrate according to another embodiment of the present disclosure. In this case, FIGS. 7A to 7F relate to cross-sections I-I′ and II-II′ of FIG. 2. Meanwhile, since the embodiments of FIGS. 7A to 7F are identical to the embodiments of FIG. 6, identical components are given the same reference numerals and repeated descriptions are omitted.

First, as can be seen in FIG. 7A, the light blocking layer 205 of the second thin film transistor TR2 and the first capacitor electrode 310 of the storage capacitor Cst are patterned on the first substrate 100a, the buffer layer 110 is disposed on the light blocking layer 205 and the first capacitor electrode 310, the first active layer 120 of the first thin film transistor TR1 is pattern-formed, the first gate insulating layer 130 is disposed on the buffer layer 110 and the first active layer 120, and a hydrogen supply material layer HSLa can be disposed on the first gate insulating layer 130. Meanwhile, the process cross-sectional view of FIG. 7A is the same as the process cross-sectional view of FIG. 5A, so a repeated description will be omitted.

Next, as can be seen in FIG. 7B, the hydrogen supply material layer HSLa can be patterned to form the hydrogen supply layer HSL in the area where the first thin film transistor TR1 is formed. Meanwhile, the process cross-sectional view of FIG. 7B is the same as the process cross-sectional view of FIG. 5B so a repeated description will be omitted.

Next, as can be seen in FIG. 7C, the first hydrogen barrier layer HBLa can be disposed on the first gate insulating layer 130 and the hydrogen supply layer HSL. The first hydrogen barrier layer HBLa can be disposed on the entire surface of the first substrate 100a.

The first hydrogen barrier layer HBLa can be formed using, for example, atomic layer deposition (ALD), plasma enhanced atomic layer deposition (PEALD), or metal organic atomic layer deposition (MOALD). But embodiments of the present disclosure are not limited thereto.

The first hydrogen barrier layer HBLa may include, but is not limited to, for example, any of silicon oxide (SiO₂), aluminum oxide (Al₂O₃) and titanium oxide (TiO₂) formed by the above metal organic atomic layer deposition (MOALD) method.

By forming the first hydrogen barrier layer HBLa by the metal organic atomic layer deposition (MOALD), the first hydrogen barrier layer HBLa can be formed into a film having excellent film quality and relatively high density. By forming it in this way, the hydrogen content inside the first hydrogen barrier layer HBLa can be relatively low.

Next, as can be seen in FIG. 7D, the second active layer 220 of the second thin film transistor TR2 and the second capacitor electrode 320 of the storage capacitor Cst can be patterned on the first hydrogen barrier layer HBLa. In this case, the second active layer 220 and the second capacitor electrode 320 can be formed using the same material in the same process, but are not limited thereto.

Next, as can be seen in FIG. 7E, the second hydrogen barrier layer HBLb can be disposed on the first hydrogen barrier layer HBLa, the second active layer 220, and the second capacitor electrode 320. The second hydrogen barrier layer HBLb can be disposed on the entire surface of the first substrate 100a.

The second hydrogen barrier layer HBLb can be formed, for example, using atomic layer deposition (ALD), plasma enhanced atomic layer deposition (PEALD), or metal organic atomic layer deposition (MOALD). But embodiments of the present disclosure are not limited thereto.

The second hydrogen barrier layer HBLb may include, but is not limited to, for example, any of silicon oxide (SiO₂), aluminum oxide (Al₂O₃) and titanium oxide (TiO₂) formed by the above metal organic atomic layer deposition (MOALD) method.

By forming the second hydrogen barrier layer HBLb by the metal organic atomic layer deposition (MOALD), the second hydrogen barrier layer HBLb can be formed into a film having excellent film quality and relatively high density. By forming it in this way, the hydrogen content inside the second hydrogen barrier layer HBLb can be relatively low.

Finally, as can be seen in FIG. 7F, the second gate insulating layer 140 can be disposed on the second hydrogen barrier layer HBLb, and the first gate electrode 150 and the second gate electrode 250 can be disposed on the second gate insulating layer 140. In this case, the first gate electrode 150 and the second gate electrode 250 can be formed using the same material in the same process, but are not limited thereto. Furthermore, by performing a conductorizing process using each of the first gate electrode 150 and the second gate electrode 250 as a mask, the first channel part 121, the first connection part 123a, and the second connection part 123b can be formed in the first active layer 120, and the second channel part 221, the first connection part 223a, and the second connection part 223b can be formed in the second active layer 220.

The interlayer insulating layer 160 is disposed on the first gate electrode 150 and the second gate electrode 250, and the first source electrode 171, the first drain electrode 173, the second source electrode 271, and the second drain electrode 273 can be disposed on the interlayer insulating layer 160. In this case, the first source electrode 171, the first drain electrode 173, the second source electrode 271, and the second drain electrode 273 can be formed using the same material in the same process, but are not limited thereto.

With reference to FIGS. 6-7F, each of the first hydrogen barrier layer HBLa and the second hydrogen barrier layer HBLb need not be formed entirely over or under the hydrogen supply layer HSL and/or the second active layer 220. For example, the second hydrogen barrier layer HBLb can be formed on the first hydrogen barrier layer HBLa over the hydrogen supply layer HSL but not on the second active layer 220 and/or the second capacitor electrode 320.

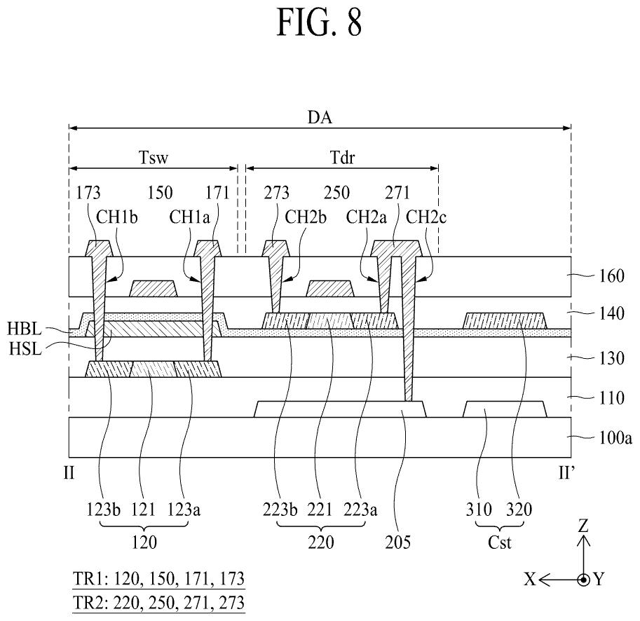

FIG. 8 is a cross-sectional view of a thin film transistor substrate according to another embodiment of the present disclosure. In this case, FIG. 8 is related to cross-section II-II′ of FIG. 2.

The first thin film transistor TR1 and the above second thin film transistor TR2 can constitute one or the other of a plurality of thin film transistors disposed in the display area see DA of FIG. 2.

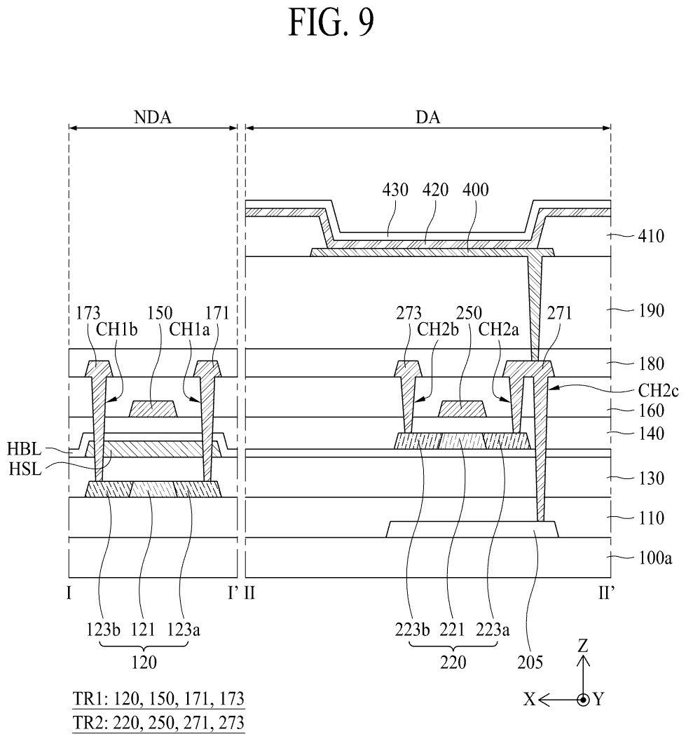

As can be seen in FIG. 9, the first thin film transistor TR1 and the second thin film transistor TR2 can be a driving thin film transistor Tdr or a switching thin film transistor Tsw among the plurality of thin film transistors disposed in the plurality of pixels (see P of FIG. 2). For example, the first thin film transistor TR1 can constitute the switching thin film transistor Tsw, and the second thin film transistor TR2 can constitute the driving thin film transistor Tdr.

According to another embodiment of the present disclosure, the first thin film transistor TR1 constitutes the switching thin film transistor Tsw and the second thin film transistor TR2 constitutes the driving thin film transistor Tdr, thereby enabling implementation of a switching thin film transistor having high on-current characteristic and implementing a driving thin film transistor having improved reliability of the device.

Meanwhile, the thin film transistor substrate according to the embodiment of FIG. 8 can be formed by including a double layer structure of a first hydrogen barrier layer and a second hydrogen barrier layer (see HBLa and HBLb of FIG. 6), like the thin film transistor substrate according to the embodiment of FIG. 6. Meanwhile, the description of the first hydrogen barrier layer and the second hydrogen barrier layer (see HBLa and HBLb of FIG. 6) is the same as that in FIG. 6, so a repeated description will be omitted.

FIG. 9 is a cross-sectional view of a display device including a thin film transistor substrate according to one embodiment of the present disclosure.

As can be seen in FIG. 9, a display device according to an embodiment of the present disclosure includes a first substrate 100a, a buffer layer 110, a first thin film transistor TR1, a second thin film transistor TR2, a storage capacitor Cst, a first gate insulating layer 130, a hydrogen supply layer HSL, a hydrogen barrier layer HBL, a second gate insulating layer 140, an interlayer insulating layer 160, a passivation layer 180, a planarization layer 190, a first electrode 400, a bank layer 410, a light emitting layer 420, and a second electrode 430.

Meanwhile, the first substrate 100a, buffer layer 110, first thin film transistor TR1, second thin film transistor TR2, storage capacitor Cst, first gate insulating layer 130, hydrogen supply layer HSL, hydrogen barrier layer HBL, second gate insulating layer 140, and interlayer insulating layer 160 are the same as those in the above-described embodiments, and therefore, a repeated description thereof will be omitted.

The passivation layer 180 can be disposed on the first source electrode 171, the first drain electrode 173, the second source electrode 271, and the second drain electrode 273. The passivation layer 180 can be formed over the entire area of the display area DA and the non-display area NDA. The passivation layer 180 can be formed in the non-display area NDA to prevent moisture or oxygen from flowing into the first thin film transistor TR1, and can be formed in the display area DA to prevent moisture or oxygen from flowing into the second thin film transistor TR2.

The passivation layer 180 can include, but is not limited to, a silicon nitride film (SiNx) or a silicon oxide film (SiOx). The passivation layer 180 can be formed of a single layer or multiple layers including an inorganic insulator and/or an organic insulator.

The flattening layer 190 can be disposed on the passivation layer 180. In this case, the flattening layer 190 can be formed in the display area DA, but is not limited thereto, and can also be formed in the non-display area NDA.

The flattening layer 190 is disposed with a contact hole, so that a part of the upper surface of the second source electrode 271 can be exposed through the contact hole. However, depending on the case, a part of the upper surface of the second drain electrode 273 can be exposed through the contact hole.

The first electrode 400 is disposed on the flattening layer 190 and is connected to the second source electrode 271 or the second drain electrode 273 through the contact hole. The first electrode 400 can function as an anode.

The bank layer 410 is provided to cover the edge of the first electrode 400 and defines a light emitting area. Accordingly, the upper surface area of the first electrode 400 that is exposed and not covered by the bank layer 410 becomes a light emitting area.

The light emitting layer 420 is disposed on the first electrode 400. The light emitting layer 420 can be formed by including red, green, and blue light emitting layers patterned for each pixel, or can be formed by a white light emitting layer connected to all pixels. When the light emitting layer 420 is formed by a white light emitting layer, the light emitting layer 420 can be formed by including, for example, a first stack including a blue light emitting layer, for example, a second stack including a yellow-green light emitting layer, and a charge generation layer provided between the first stack and the second stack, but is not necessarily limited thereto.

The second electrode 430 is disposed on the light emitting layer 420. The second electrode 430 can function as a cathode.

A sealing layer can be additionally disposed on the second electrode 430 to prevent the penetration of moisture or oxygen.

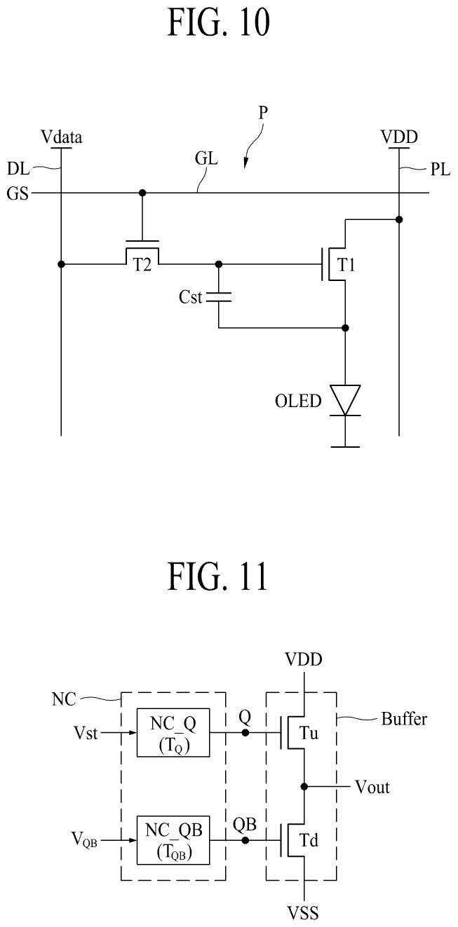

FIG. 10 is a circuit diagram of one pixel disposed in a display device according to one embodiment of the present disclosure.

As can be seen in FIG. 10, a display device according to one embodiment of the present disclosure comprises first and second thin film transistors T1, T2 and a capacitor Cst.

The first thin film transistor T1 is a driving thin film transistor, and the second thin film transistor T2 is a switching thin film transistor. At least one of the first thin film transistor T1 and the second thin film transistor T2 can be formed of various thin film transistors as described above.

The first thin film transistor T1 is switched according to the data voltage Vdata supplied from the second thin film transistor T2 to generate a data current from the driving voltage VDD supplied from the power line PL and supply it to the organic light emitting diode OLED.

The second thin film transistor T2 is switched according to a gate signal GS supplied to the gate line GL and supplies a data voltage Vdata supplied from a data line DL to the first thin film transistor T1.

The capacitor Cst serves to maintain the data voltage supplied to the first thin film transistor T1 for one frame, and is provided between the gate electrode and the source electrode of the first thin film transistor T1.

The organic light emitting diode OLED emits a predetermined amount of light according to the data current supplied from the first thin film transistor T1.

FIG. 11 is a circuit diagram of a shift register according to one embodiment of the present disclosure.

As can be seen in FIG. 11, the GIP circuit consists of a pull up node Q, a pull down node QB, a node control unit NC, and a buffer unit Buffer.

The buffer unit is connected to the output terminal and includes a pull up transistor Tu, a pull down transistor Td, and a capacitor C.

The pull up transistor Tu is turned on when the pull up node Q is charged to a gate high voltage and outputs the gate on signal.

The pull down transistor Td is turned on when the pull down node QB is charged to the gate low voltage and outputs the gate off signal.

At least one of the pull up transistor Tu and the pull down transistor Td can be formed of various thin film transistors as described above.

The capacitor C serves to maintain the gate high voltage supplied to the pull up transistor Tu for one frame, and is provided between the gate terminal and the source terminal of the pull up transistor Tu.

The node control unit NC controls charging and discharging of the pull up node Q and the pull down node QB. The node control unit NC can include a pull up node control unit NC_Q for controlling charging and discharging of the pull up node Q and a pull down node control unit NC_QB for controlling charging and discharging of the pull down node QB. The pull up node control unit NC_Q includes at least one transistor T for controlling the pull up node Q, and the pull down node control unit NC_QB includes at least one transistor T for controlling the pull down node QB.

The output of the gate signal Vout can be stably controlled by the above node control unit NC. In detail, the node control unit NC discharges the pull down node QB to a gate low voltage when the pull up node Q is charged to a gate high voltage, and discharges the pull up node Q to a gate low voltage when the pull down node QB is charged to a gate high voltage.

Therefore, when the start signal Vst is applied, multiple transistors T disposed in the node control unit TQ, TQB by the operation of the pull up node Q is charged to the gate high voltage and the pull down node QB is discharged to the gate low voltage to output the high power voltage VDD as the gate signal Vout. In addition, the discharge signal VQB is authorized, a plurality of transistors T disposed in the node control unit TQ, TQB by the operation of the pull up node Q is charged to the gate low voltage and the pull down node QB is charged to the gate high voltage to output the low power voltage VSS as the gate signal Vout.

Although the embodiments of the present disclosure have been described in more detail with reference to the attached drawings, the present disclosure is not necessarily limited to these embodiments, and various modifications can be made without departing from the technical idea of the present disclosure. Accordingly, the embodiments disclosed in the present disclosure are not intended to limit the technical idea of the present disclosure, but to explain it, and the scope of the technical idea of the present disclosure is not limited by these embodiments. Therefore, it should be understood that the embodiments described above are examples in all aspects and not restrictive. The protection scope of the present disclosure should be interpreted by the claims, and all technical ideas within a scope equivalent thereto should be interpreted as being included in the scope of the claims of the present disclosure.

According to the present disclosure as described above, the following effects are achieved.

According to one embodiment of the present disclosure, hydrogen is sufficiently supplied to a polycrystalline silicon thin film transistor by a hydrogen supply layer patterned to correspond to a region in which a first thin film transistor including a polycrystalline silicon semiconductor material is formed, thereby improving the device characteristic of the first thin film transistor.

According to one embodiment of the present disclosure, by forming a hydrogen barrier layer in a region where a second thin film transistor including an oxide semiconductor material is formed, hydrogen can be prevented from flowing in from insulating layers provided adjacent to a second active layer of the second thin film transistor. Accordingly, it is possible to prevent the characteristic of the second thin film transistor from changing due to hydrogen.

According to one embodiment of the present disclosure, a hydrogen supply layer that supplies hydrogen is provided to correspond to an area where a first thin film transistor is formed, and a hydrogen barrier layer is disposed in an area where the first thin film transistor and the second thin film transistor are disposed, thereby implementing a thin film transistor substrate capable of supplying hydrogen to the first thin film transistor while blocking hydrogen from the second thin film transistor without adding a separate mask.

The effects of the present disclosure are not limited to the effects mentioned above, and other effects not mentioned will be clearly understood by those skilled in the art from the description above.

What is claimed is:

1. A thin film transistor substrate comprising:
a base substrate; and
a first thin film transistor and a second thin film transistor on the base substrate,
wherein the first thin film transistor comprises:
a first active layer disposed on the base substrate and including a silicon semiconductor material;
a hydrogen supply layer on the first active layer;
a hydrogen barrier layer on the hydrogen supply layer; and
a first gate electrode on the hydrogen barrier layer, and
wherein the second thin film transistor comprises:
a second active layer on the hydrogen barrier layer and including an oxide semiconductor material; and
a second gate electrode on the second active layer.

2. The thin film transistor substrate of claim 1,
wherein the hydrogen supply layer is disposed to entirely overlap the first active layer.

3. The thin film transistor substrate of claim 1,
wherein the first gate electrode and the second gate electrode are disposed in a same layer.

4. The thin film transistor substrate of claim 1 further comprising;
a first gate insulating layer disposed between the first active layer and the hydrogen supply layer,
wherein a hydrogen content in the hydrogen barrier layer is less than a hydrogen content in the first gate insulating layer.

5. The thin film transistor substrate of claim 4,
wherein a thickness of the hydrogen barrier layer is less than a thickness of the first gate insulating layer.

6. The thin film transistor substrate of claim 1 further comprising:
a second gate insulating layer disposed between the second active layer and the second gate electrode,
wherein a hydrogen content in the first hydrogen barrier layer is less than a hydrogen content in the second gate insulating layer.

7. The thin film transistor substrate of claim 6,
wherein a thickness of the hydrogen barrier layer is less than a thickness of the second gate insulating layer.

8. The thin film transistor substrate of claim 1,
wherein a thickness of the hydrogen barrier layer is less than a thickness of the second active layer.

9. The thin film transistor substrate of claim 1,
wherein the hydrogen barrier layer is disposed over an entire surface of the base substrate.

10. The thin film transistor substrate of claim 1 further comprising:
another hydrogen barrier layer disposed between the second active layer and the second gate electrode,
wherein the another hydrogen barrier layer is disposed to cover the second active layer.

11. The thin film transistor substrate of claim 10,
wherein the hydrogen barrier layer and the another hydrogen barrier layer are in contact with each other.

12. The thin film transistor substrate of claim 10,
wherein the second hydrogen barrier layer is disposed over an entire surface of the base substrate.

13. The thin film transistor substrate of claim 1,
wherein the hydrogen barrier layer includes any one of SiO₂, Al₂O₃, or TiO₂ formed by atomic layer deposition, and
wherein the hydrogen supply layer includes silicon nitride formed by plasma enhanced chemical vapor deposition.

14. A thin film transistor substrate comprising:
a base substrate including a display area and a non-display area;
a first thin film transistor on the base substrate and including a silicon semiconductor material;
a second thin film transistor including an oxide semiconductor material;
a hydrogen barrier layer disposed to overlap the first thin film transistor and second thin film transistor; and
a hydrogen supply layer disposed to overlap the first thin film transistor,
wherein the hydrogen supply layer does not overlap the second thin film transistor.

15. The thin film transistor substrate of claim 14,
wherein a pixel including a plurality of thin film transistors is disposed in the display area,
wherein a gate driver circuit including the plurality of thin film transistors is disposed in the non-display area,
wherein at least one of the plurality of thin film transistors included in the gate driver circuit comprises the first thin film transistor, and
wherein at least one of the plurality of thin film transistors included in the pixel comprises the second thin film transistor.

16. The thin film transistor substrate of claim 14,
wherein a pixel including a plurality of thin film transistors is disposed on the display area,
wherein a gate driver circuit including the plurality of thin film transistors is disposed on the non-display area,
wherein the plurality of thin film transistors including in the pixel comprise a switching thin film transistor and a driving thin film transistor,
wherein the switching thin film transistor includes the first thin film transistor, and
wherein the driving thin film transistor includes the second thin film transistor.

17. The thin film transistor substrate of claim 14, further comprising:
another hydrogen barrier layer on the hydrogen barrier layer and overlapping the first thin film transistor and second thin film transistor.

18. The thin film transistor substrate of claim 1,
wherein the second thin film transistor further comprises a light blocking layer which is disposed under the second active layer and overlaps with the second active layer.

19. A display device comprising the thin film transistor substrate according to claim 1.

20. A display substrate comprising:
a first thin film transistor;
a first gate insulating layer on the first thin film transistor;
a hydrogen barrier layer on the first gate insulating layer; and
a second thin film transistor on the hydrogen blocking layer,
a second gate insulating layer on the second thin film transistor,
wherein the first thin film transistor comprises a first active layer including a silicon semiconductor material,
wherein the second thin film transistor comprises a second active layer including an oxide semiconductor material, and
wherein an amount of hydrogen contained inside the hydrogen barrier layer is less than an amount of hydrogen contained in the first gate insulating layer and an amount of hydrogen contained in the second gate insulating layer.

21. The display substrate of claim 19, further comprising a hydrogen supply layer located between the first gate insulating layer and the hydrogen barrier layer.
